(19) United States
(12) Patent Application Publication
(10) Pub. No.: US 2018/0138408 A1
(43) Pub. Date: May 17, 2018

(54) A SHADOW MASK FOR ORGANIC LIGHT EMITTING DIODE MANUFACTURE

(71) Applicant: Applied Materials, Inc., Santa Clara, CA (US)

(72) Inventors: Brian E. LASSITER, San Francisco, CA (US); Dieter HAAS, San Jose, CA (US); Xi HUANG, Shanghai (CN)

(21) Appl. No.: 15/112,121

(22) PCT Filed: Aug. 5, 2015
(86) PCT No.: PCT/CN2015/086106

§ 371 Date: Jul. 15, 2016

(51) Int. Cl. H01L 51/00; C23C 14/04; C25D 1/10; C25D 1/20; H01L 51/56

(52) U.S. Cl. CPC H01L 51/0011; C23C 14/042; H01L 51/56; C25D 1/20; C25D 1/10

(57) ABSTRACT

A shadow mask (200) includes a frame (210) made of a metallic material, and one or more mask patterns (205) coupled to the frame (210), the one or more mask patterns (205) comprising a metallic material having a coefficient of thermal expansion less than or equal to about 14 microns/meter/degrees Celsius and having a plurality of openings (215) formed therein, the metallic material having a thickness of about 5 microns to about 50 microns and having a pitch tolerance between openings (215) of about +/−3 microns across a length of about 160 millimeters.

### BACKGROUND

### Field of the Disclosure

Embodiments of the disclosure relate to formation of electronic devices on substrates utilizing fine patterned shadow masks. In particular, embodiments disclosed herein relate to a method and apparatus for a fine patterned metal mask utilized in the manufacture of organic light emitting diodes (OLED's).

### Description of Related Art

In the manufacture of flat panel displays for television screens, cell phone displays, computer monitors, and the like, OLED's have attracted attention. OLED's are a special type of light-emitting diodes in which a light-emissive layer comprises a plurality of thin films of certain organic compounds. OLED's can also be used for general space illumination. The range of colors, brightness, and viewing angle possible with OLED displays are greater than those of traditional displays because OLED pixels emit light directly and do not require a back light. Therefore, the energy consumption of OLED displays is considerably less than that of traditional displays. Further, the fact that OLED's can be manufactured onto flexible substrates opens the door to new applications such as roll-up displays or even displays embedded in flexible media.

Current OLED manufacturing requires evaporation of organic materials and deposition of metals on a substrate utilizing a plurality of patterned shadow masks. Temperatures during evaporation and/or deposition require the material of the masks to be made of a material having a low coefficient of thermal expansion (CTE). The low CTE prevents or minimizes movement of the mask relative to the substrate. Thus, masks may be made from metallic materials having a low CTE. Typically, the masks are made by rolling a metallic sheet having a thickness of about 200 microns (μm) to about 1 millimeter to a desired thickness (e.g., about 20 μm to about 50 μm). A photoresist is formed on the rolled metal sheet in a desired pattern and exposed to light in a photolithography process. Then, the rolled metal sheet having the pattern formed by photolithography is then chemically etched to create fine openings therein.

However, the conventional mask forming processes have limitations. For example, etch accuracy becomes more difficult with increasing resolution requirements. Additionally, substrate surface area is constantly increasing in order to increase yield and/or make larger displays, and the masks may not be large enough to cover the substrate. This is due to the limited availability of sheet sizes for the low CTE material, and, even after rolling, fails to have a surface area that is sufficient. Further, increased resolution of the fine patterns requires thinner sheets. However, rolling and handling of sheets with a thickness of less than 30 μm is difficult.

Therefore, there is a need for an improved fine metal shadow mask and method for making the fine metal shadow mask.

### SUMMARY

Embodiments of the disclosure provide methods and apparatus for a fine patterned shadow mask for organic light emitting diode manufacture.

In one embodiment, a shadow mask is provided and includes a frame made of a metallic material, and one or more mask patterns coupled to the frame, the one or more mask patterns comprising a metallic material having a coefficient of thermal expansion less than or equal to about 14 microns/meter/degrees Celsius and having a plurality of openings formed therein, the metallic material having a thickness of about 5 microns to about 50 microns and having a pitch tolerance between openings of about +/−3 microns across a length of about 160 millimeters.

In another embodiment, a mask pattern is provided and includes a mandrel comprising a conductive material and having a coefficient of thermal expansion less than or equal to about 14 microns/meter/degrees Celsius, and a dielectric material having a plurality of openings formed therein exposing at least a portion of the conductive material, the dielectric material comprising a pattern of volumes, each of the volumes having a major dimension of about 5 microns to about 20 microns.

In another embodiment, a method for forming a shadow mask is provided and includes preparing a mandrel comprising a conductive material and having a coefficient of thermal expansion less than or equal to about 7 microns/meter/degrees Celsius, depositing a dielectric material onto the mandrel in a pattern having a plurality of openings formed therein exposing at least a portion of the conductive material, wherein the pattern of includes a plurality of volumes, each of the volumes having a major dimension of about 5 microns to about 20 microns, placing the mandrel into an electrolytic bath comprising a material having a coefficient of thermal expansion less than or equal to about 14 microns/meter/degrees Celsius, and electroforming a plurality of borders in the openings of the mandrel.

In another embodiment, an electroformed mask is provided. The electroformed mask is formed by preparing a mandrel comprising a metal layer and a pattern area having openings formed therein exposing a portion of the metal layer, the mandrel having a coefficient of thermal expansion less than or equal to about 7 microns/meter/degrees Celsius, exposing the mandrel to an electrolytic bath, electrodepositing a metallic material having a coefficient of thermal expansion less than or equal to about 14 microns/meter/degrees Celsius in the openings, removing the mandrel from the bath, and separating the mask from the mandrel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is an isometric exploded view of an OLED device that may be manufactured utilizing embodiments described herein.

FIG. 2 is a schematic plan view of one embodiment of a fine metal mask.

FIGS. 3A-3C are schematic partial sectional views illustrating a formation method for one embodiment of a fine metal mask.

FIGS. 4A-4B are schematic partial sectional views illustrating another embodiment of a formation method for a fine metal mask.

FIG. 5A and 5B are schematic partial sectional views illustrating another embodiment of a formation method for a fine metal mask.

FIGS. 6A-6B are schematic partial sectional views illustrating a formation method for another embodiment of a fine metal mask.

FIGS. 7A-7B are schematic partial sectional views illustrating a formation method for another embodiment of a fine metal mask.

FIG. 8 is a schematic partial sectional view illustrating a formation method for another embodiment of a fine metal mask.

FIG. 9 schematically illustrates one embodiment of an apparatus for forming an OLED device on a substrate.

FIG. 10 is a schematic plan view of a manufacturing system according to one embodiment.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the disclosure provide methods and apparatus for a fine metal mask that may be used as a shadow mask in the manufacture of organic light emitting diodes (OLED's). For example, a fine metal mask that is utilized in a vacuum evaporation or deposition process where multiple layers of thin films are . deposited on the substrate. As an example, the thin films may form a portion of a display or displays on the substrate comprising OLED's. The thin films may be derived from organic materials utilized in the fabrication of OLED displays. The substrate may be made of glass, plastic, metal foil, or other material suitable for electronic device formation. Embodiments disclosed herein may be practiced in chambers and/or systems available from AKT, Inc., a division of Applied Materials, Inc., of Santa Clara, Calif. Embodiments disclosed herein may also be practiced in chambers and/or systems from other manufacturers.

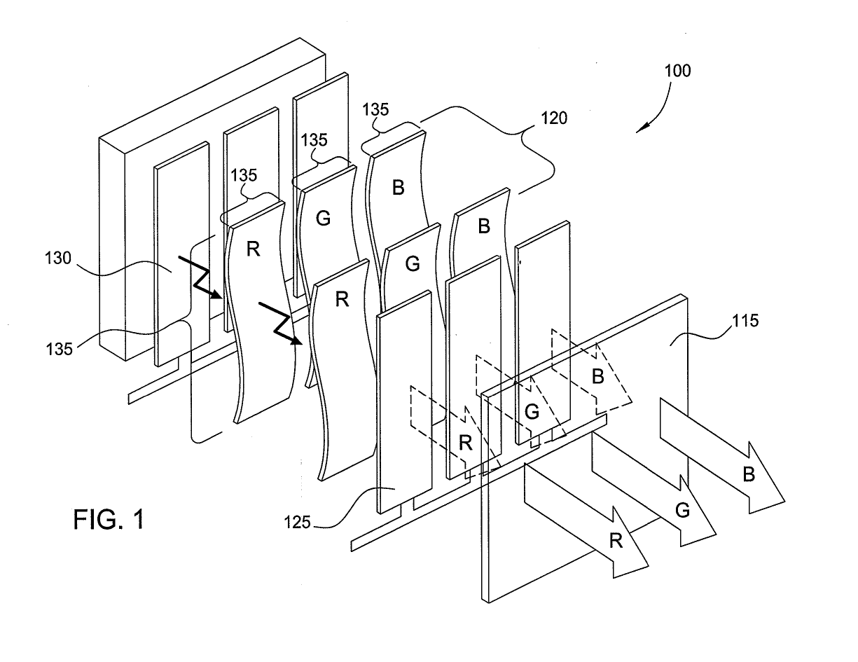

FIG. 1 is an isometric exploded view of an OLED device 100. The OLED device 100 may be formed on a substrate 115. The substrate 115 may be made of glass, transparent plastic, or other transparent material suitable for electronic device formation. In some OLED devices, the substrate 115 may be a metal foil. The OLED device 100 includes one or more organic material layers 120 sandwiched between two electrodes 125 and 130. The electrode 125 is may be a transparent material such as indium tin oxide (ITO), or silver (Ag), and may function as an anode or a cathode. In some OLED devices, transistors (not shown) may also be disposed between the electrode 125 and the substrate 115. The electrode 130 may be a metallic material and function as a cathode or anode. Upon power application to the electrodes 125 and 130, light is generated in the organic material layers 120. The light may be one or a combination of red R, green G and blue B generated from corresponding RGB films of the organic material layers 120. Each of the red R, green G and blue B organic films may comprise a sub-pixel active area 135 of the OLED device 100. Variations of materials and the position of the cathode and anode are dependent on the type of display where the OLED device is utilized. For example, in “top illumination” displays, light is emitted through the cathode side of the device and in “bottom illumination” devices light may be emitted through the anode side.

Although not shown, the OLED device 100 may also include one or more hole injection layers as well as one or more electron transporting layers disposed between the electrodes 125 and 130 and the organic material layers 120. Additionally, while not shown, the OLED device 100 may include a film layer for white light generation. The film layer for white light generation may be a film in the organic material layers 120 and/or a filter sandwiched within the OLED device 100. The OLED device 100 may form a single pixel as is known in the art. The organic material layers 120, and the film layer for white light generation (when used), as well as the electrodes 125 and 130, may be formed using a fine metal mask as described herein.

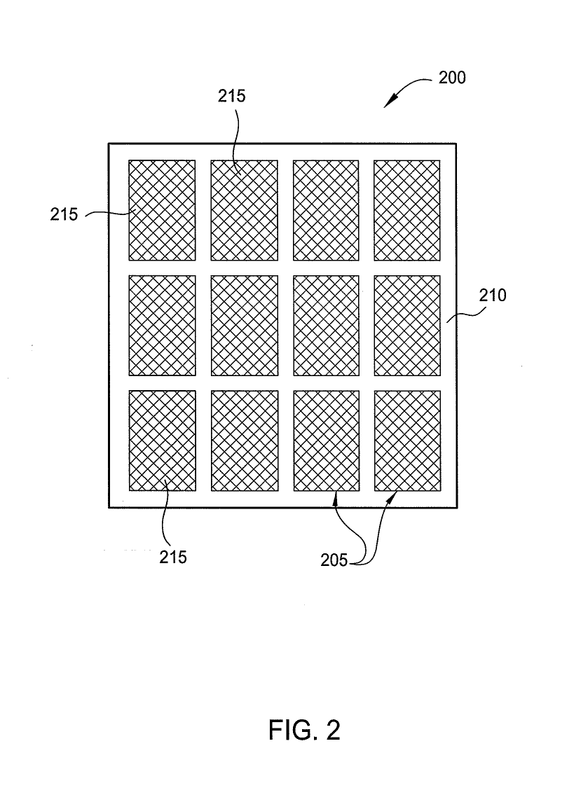

FIG. 2 is a schematic plan view of one embodiment of a fine metal mask 200. The fine metal mask 200 includes a plurality of pattern areas 205 that are coupled to a frame 210. The pattern areas 205 are utilized to control deposition of materials on a substrate. For example, the pattern areas 205 may be utilized to control evaporation of organic materials and/or metallic materials in the formation of the OLED device 100 as shown and described in FIG. 1. The pattern areas 205 have a series of fine openings 215 that blocks deposited materials from attaching to undesired areas of a substrate or on previously deposited layers. The fine openings 215 thus provide deposition on specified areas of a substrate or on previously deposited layers. The fine openings 215 may be round, oval or rectangular. The fine openings 215 may include a major dimension (e.g., a diameter or other inside dimension) of about 5 microns (μm) to about 20 μm, or greater. The pattern areas 205 typically include a cross-sectional thickness on the order of about 5 μm to about 100 μm, such as about 10 μm to about 50 μm. The pattern areas 205 may be coupled to the frame 210 by welding or fasteners (not shown). In one example, a single mask sheet having multiple pattern areas 205 disposed thereon may be tensioned and welded to the frame 210. In another example, a plurality of strips, each having multiple pattern areas 205 having widths similar to a to-be-manufactured display, may be tensioned and welded to the frame 210. The frame 210 may have a cross-sectional thickness of about 10 millimeters (mm) or less in order to provide stability to the fine metal mask 200.

The pattern areas 205 as well as the frame 210 may be made of a material having a low coefficient of thermal expansion (CTE) which resists movement of the fine openings 215 during temperature changes. Examples of materials having a low CTE include molybdenum (Mo), titanium (Ti), chromium (Cr), tungsten (W), tantalum (Ta), vanadium (V), alloys thereof and combinations thereof, as well as alloys of iron (Fe) and nickel (Ni), among other low CTE materials. The low CTE material maintains dimensional stability in the fine metal mask 200 which provides accuracy of the deposited materials. Low CTE materials or metals as described herein may be a CTE of less than or equal to about 15 microns/meter/degrees Celsius, such as less than or equal to about 14 microns/meter/degrees Celsius, for example less than or equal to about 13 microns/meter/degrees Celsius.

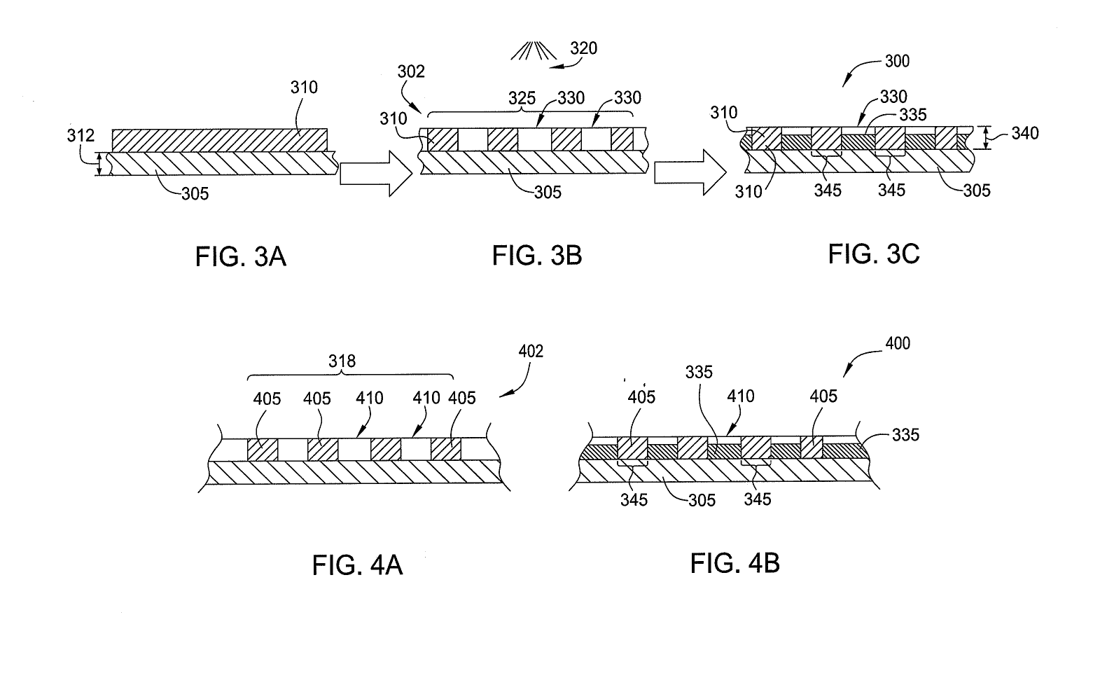

FIGS. 3A-3C are schematic partial sectional views illustrating a formation method for one embodiment of a fine metal mask 300. A portion of the fine metal mask 300 is shown in FIG. 3C. The method includes a mask pattern 302 used to form the fine metal mask 300. The mask pattern 302 includes a mandrel 305 coated with an organic photoresist 310. A thickness 312 of the mandrel 305 may be about 0.1 millimeters (mm) to about 10 mm. The thickness of the photoresist 310 may be greater than a desired thickness of the fine metal mask 300. The photoresist 310 may then be patterned utilizing known photolithography techniques. In FIG. 3B, the photoresist 310 is exposed to light 320 to provide a patterned photoresist 325. A mask (not shown) may be placed above the photoresist 310 to provide a desired pattern for the openings in the fine metal mask 300. After exposure and developing according to photolithography techniques, the patterned photoresist 325 has a plurality of openings 330 formed therein where portions of the mandrel 305 are exposed.

In FIG. 3C, the mask pattern 302, having the patterned photoresist 315 formed thereon, is placed in an electrolytic bath (not shown). The bath includes a material with a low CTE metal dissolved therein. Examples of materials having a low CTE include molybdenum (Mo), titanium (Ti), chromium (Cr), tungsten (W), tantalum (Ta), vanadium (V), alloys thereof and combinations thereof, as well as alloys of iron (Fe) and nickel (Ni), alloys of iron (Fe), nickel (Ni) and cobalt (Co), among other low CTE materials. Examples of Fe:Ni alloys and Fe:Ni:Co alloys may include metals marketed under the trade names INVAR® (Fe:Ni 36), SUPER INVAR 32-5®, among others. According to electroforming techniques, an electrical bias is provided between the mandrel 305 and the low CTE metal in the bath. The openings 330 are then filled with the low CTE metal to form borders 335 of the fine metal mask 300. The borders 335 surround and isolate the photoresist 310 remaining on the mandrel 305. At least a portion of the borders 335 comprises a pattern area 318 similar to a portion of the pattern areas 205 of the fine metal mask 200 of FIG. 2. The borders 335 are integral to the fine metal mask 300 and the fine metal mask 300 may be peeled away or otherwise separated from the mandrel 305 and the remaining photoresist 310. Another method may include chemically and/or physically removing the remaining photoresist 310. Volumes 345 between the borders 335 will provide the fine openings 215 as described in FIG. 2 when the fine metal mask 300 is removed from the mandrel 305. The borders 335 may be formed to a desired height 340, which is the thickness of the pattern area 205 of the fine metal mask 200 of FIG. 2. In some embodiments, the height 340 is about 5 μm to about 100 μm.

The mandrel 305 may be a metallic material having a CTE lower than the CTE of the fine metal mask 300, such as ultra-low CTE materials. Ultra-low CTE may be defined as a material having a coefficient of expansion less than or equal to about 7 microns/meter/degrees Celsius (μm/m/° C.). An additional material for the mandrel 305 may be glass, quartz and fused silica. Utilizing ultra-low CTE materials can improve accuracy in the positioning of the fine openings 215 (e.g., the positioning of the borders 335 of the fine metal mask 300). For example, minor temperature variations in the electrolytic bath may cause the mandrel 305 to expand or contract. In one example, if stainless steel is used for the mandrel 305 having a surface area of about 1 meter square, a 1.0 degrees Celsius change in temperature would result in a 14 μm position change. The resulting mask using a stainless steel mandrel would result in pattern inaccuracies.

For high resolution displays, the pattern accuracy should be less than about 7 μm, and more particularly, less than about 5 μm. High resolution may be defined as a display having a pixel density greater than about 400 pixels per inch (ppi), such as 500 ppi to about 800 ppi, and up to about 1,000 ppi.

Other properties of the mandrel 305 may include thickness, conductivity, surface finish, and flatness. The cross sectional thickness of the mandrel 305 may be about 0.1 mm to about 10 mm. The mandrel 305 may have a resistivity of less than or equal to about 100 micro Ohms·meter (μΩ·m). The mandrel 305 may have an average surface roughness (Ra) that is less than about 100 nanometers (nm). The mandrel 305 may have a flatness tolerance of less than about 50 μm.

FIGS. 4A-4B are schematic partial sectional views illustrating another embodiment of a formation method for a fine metal mask 400. The method includes a mask pattern 402 used to form the fine metal mask 400. The method is substantially the same as the formation method described in FIGS. 3A-3C with the following exceptions. According to this embodiment, the mandrel 305 may comprise cobalt (Co). The specifications for the mandrel 305 may be similar to the embodiment described in FIGS. 3A-3C but instead of coating the mandrel 305 with a photoresist as described in FIGS. 3A-3C, the mandrel 305 is coated with a deposited dielectric material 405 to form the mask pattern 402.

The dielectric material 405 may be an inorganic material such as silicon nitride (e.g., SiN, Si₃N₄), silicon oxide (e.g., SiO₂), titanium dioxide (e.g., TiO₂), aluminum oxide (e.g., Al₂O₃), or mixtures thereof, among other suitable inorganic oxides and/or nitrides. The dielectric material 405 may be deposited by a vacuum process, such as chemical vapor deposition (CVD), sputtering, evaporation, or other suitable vacuum deposition process. The dielectric material 405 may be deposited to a thickness that is greater than a desired thickness of the fine metal mask 400. An example thickness for the dielectric material 405 may be about greater than 100 nm. At least a portion of the dielectric material 405 comprises a pattern area 318 similar to a portion of the pattern areas 205 of the fine metal mask 200 of FIG. 2. The dielectric material 405 may then be coated with a photoresist (not shown) and exposed to light according to photolithography techniques. The photoresist may be patterned using a mask (not shown) according to a desired pattern for the openings in the fine metal mask 400 by a photolithography process.

As shown in FIG. 4A, a plurality of openings 410 are formed in the dielectric material 405. Thereafter, the mandrel 305, having the patterned dielectric material 405 disposed thereon, is placed in an electrolytic bath (not shown). The bath includes a material with a low CTE metal dissolved therein, similar to the materials utilized in the embodiment described in FIG. 3C. An electrical bias is provided between the mandrel 305 and the low CTE metal in the bath. The openings 410 are then filled with the low CTE metal to form borders 335 of the fine metal mask 400. The borders 335 surround and isolate the dielectric material 405 remaining on the mandrel 305. Volumes 345 between the borders 335 will provide the fine openings 215 as described in FIG. 2 when the fine metal mask 400 is removed from the mandrel 305. Another method may include chemically and/or physically removing the remaining dielectric material 405. The borders 335 may be formed to a height similar to the embodiment described in FIG. 3C.

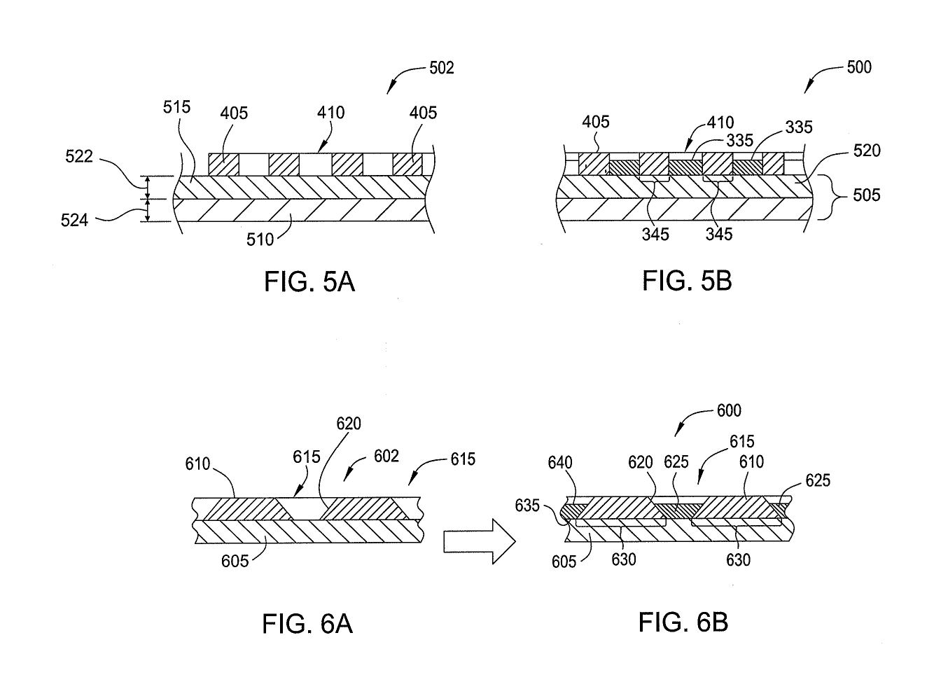

FIG. 5A and 5B are schematic partial sectional views illustrating another embodiment of a formation method for a fine metal mask 500. The method includes a mask pattern 502 used to form the fine metal mask 500. The method is substantially the same as the formation method described in FIGS. 3A-3C with the following exceptions. The formation method utilizes a multi-layer mandrel 505. The multi-layer mandrel 505 may include a first substrate 510 that is bonded or adhered to a second substrate 515. The second substrate 515 may include a metal layer 520 that is deposited on or otherwise adhered to the first substrate 510. In some embodiments, the first substrate 510 may be a glass material or a glass ceramic material having a low CTE while the metal layer 520 may have a CTE greater than the CTE of the first substrate 510.

The metal layer 520 may comprise metals used as the mandrel 305 described above, and may additionally include chromium (Cr), copper (Cu), silver (Ag), gold (Au) as well as Ni, Al, among other metals. The metal layer 520 may be deposited as a film on the first substrate 510. The metal layer 520 may have a thickness 522 of about 10 nm to about 700 nm, or less. The metal layer 520 may have a sheet resistance of less than or equal to about 100 Ohms per square (Ω/sq.). The metal layer 520 may have an average surface roughness (Ra) that is less than about 100 nm. The metal layer 520 may have a film stress resulting in less than about 50 μm warping. The metal layer 520 may be deposited by a vacuum process such as CVD, sputtering, evaporation, or other suitable vacuum deposition process.

The first substrate 510 may comprise a glass material having an ultra-low CTE. Examples include borosilicate glass, aluminosilicate glass, quartz, fused quartz, among other glasses. Other examples include a titanium silicate glass material or a glass ceramic material. Examples include a lithium aluminum silicon oxide glass ceramic material or ultra-low expansion glass marketed under the trade name ULE® by Corning Advanced Optics. The glass ceramic material may have a CTE of less than or equal to about 0.1·10⁻⁶/° C. in a temperature range between 0 degrees C. to about 50 degrees C. Other examples include an inorganic, non-porous lithium aluminum silicon oxide glass ceramic material marketed under the trade name ZERODUR®. The ultra-low expansion glass may include a CTE of less than about 1·10⁻⁶/° C. in a temperature range between 5 degrees C. to about 35 degrees C. An example of ultra-low expansion glass may include ULE®, Corning Code 7972. A thickness 524 of the first substrate 510 may be about 0.1 mm to about 10 mm. The first substrate 510 may have an average surface roughness (Ra) that is less than about 100 nm. The first substrate 510 may have a flatness tolerance of less than about 50 μm.

The second substrate 515 may comprise a plurality of metal layers. One example may include a Ti layer bonding with the first substrate 510 and a Cu layer disposed on the Ti layer. The fine metal mask 500 may be formed directly on the Cu layer according to this example. In another example, a first Ti layer may be formed on the first substrate 510 with a Cu layer deposited on the first Ti layer. Additionally, a second Ti layer may be formed on the Cu layer. The fine metal mask 500 may be formed directly on the second Ti layer according to this example. The Cu layer may be utilized to satisfy conductive properties of the multi-layer mandrel 505. Generally, a Cu layer with a thickness of about 200 nm to about 1 μm will provide a suitable electrical resistance. However, a thickness of the Cu layer may be dependent on the surface area of the first substrate 510 to provide suitable conductive properties. The second Ti layer may be utilized to optimize adhesion properties with the fine metal mask 500. Additionally, using metals with a higher resistivity in place of the Cu layer would require a thicker metal layer.

In one embodiment, a thickness of the first Ti layer may be about 5 nm to about 50 nm. The Cu layer may have a thickness of about 300 nm to about 900 nm. The second Ti layer may have a thickness of about 10 nm to about 50 nm.

A dielectric material 405 may be coated onto the second substrate 515 to form the mask pattern 502. The dielectric material 405 may be the same as the dielectric material 405 described and shown in FIGS. 4A and 4B or the photoresist 310 described in FIGS. 3A-3C. The dielectric material 405 may be the same thickness as described in FIGS. 4A and 4B or the photoresist 310 described in FIGS. 3A-3C. The dielectric material 405 may be formed by the same methods as described in FIGS. 4A and 4B. The dielectric material 405 may include the same properties as described in FIGS. 4A and 4B with the following exception. The dielectric material 405 may have a direct current (DC) resistivity of greater than or equal to about 10¹⁰ Ohms·centimeter (Ω·cm). Examples of materials for the dielectric material 405 include Si₃N₄, SiO₂, TiO₂, Al₂O₃, among other dielectric materials with the desired resistivity.

As shown in FIG. 5A, a plurality of openings 410 are formed in the dielectric material 405 after a photolithography process as described in FIGS. 4A and 4B. Thereafter, the multi-layer mandrel 505, having the patterned dielectric material 405 disposed thereon, is placed in an electrolytic bath (not shown). The bath includes a material with a low CTE metal dissolved therein, similar to the materials utilized in the embodiment described in FIG. 3C. An electrical bias is provided between the multi-layer mandrel 505 and the low CTE metal in the bath. The openings 410 are then filled with the low CTE metal to form borders 335 of the fine metal mask 500. The borders 335 surround and isolate the dielectric material 405 remaining on the multi-layer mandrel 505. Volumes 345 between the borders 335 will provide the fine openings 215 as described in FIG. 2 when the fine metal mask 500 is removed from the multi-layer mandrel 505. The borders 335 may be formed to a height similar to the embodiment described in FIG. 3C.

FIGS. 6A-6B are schematic partial sectional views illustrating a formation method for another embodiment of a fine metal mask 600. A portion of the fine metal mask 600 is shown in FIG. 6B. The fine metal mask 600 may be formed using a mask pattern 602 shown in FIG. 6A. The mask pattern 602 includes a mandrel 605 that may be the mandrel 305 described in FIGS. 3A-4B or the multi-layer mandrel 505 as described in FIGS. 5A and 5B. A dielectric material 610 is disposed on the mandrel 605 as described herein in other Figures. The dielectric material 610 may be the photoresist 310 described in FIGS. 3A-3C in one embodiment. In other embodiments, the dielectric material 610 may be the dielectric material 405 described and shown in FIGS. 4A through 5B. The dielectric material 610 may be the same thickness as the photoresist 310 described in FIGS. 3A-3C or the dielectric material 405 as described in FIGS. 4A and 4B. The dielectric material 405 may be patterned and/or formed by the same methods as described in FIGS. 3A-4B.

A plurality of openings 615 are formed in the dielectric material 610 after a photolithography process as described herein. In this embodiment, the openings 615 include a tapered sidewall 620. Thereafter, the mask pattern 602 is placed in an electrolytic bath (not shown). The bath includes a material with a low CTE metal dissolved therein, similar to the materials utilized in the embodiment described in FIG. 3C. An electrical bias is provided between the mandrel 605 and the low CTE metal in the bath. The openings 615 are then filled with the low CTE metal to form borders 625 of the fine metal mask 600. The borders 625 surround and isolate the dielectric material 610 remaining on the mandrel 605. Volumes 630 between the borders 625 will provide the fine openings 215 as described in FIG. 2 when the fine metal mask 600 is removed from the mandrel 605. The borders 625 may be formed to a height similar to the borders 335 described in FIG. 3C. The fine metal mask 600 may include a first side 635 and an opposing second side 640. The second side 640 may be placed against a substrate during formation of the sub-pixel active area 135 of the OLED device 100 of FIG. 1.

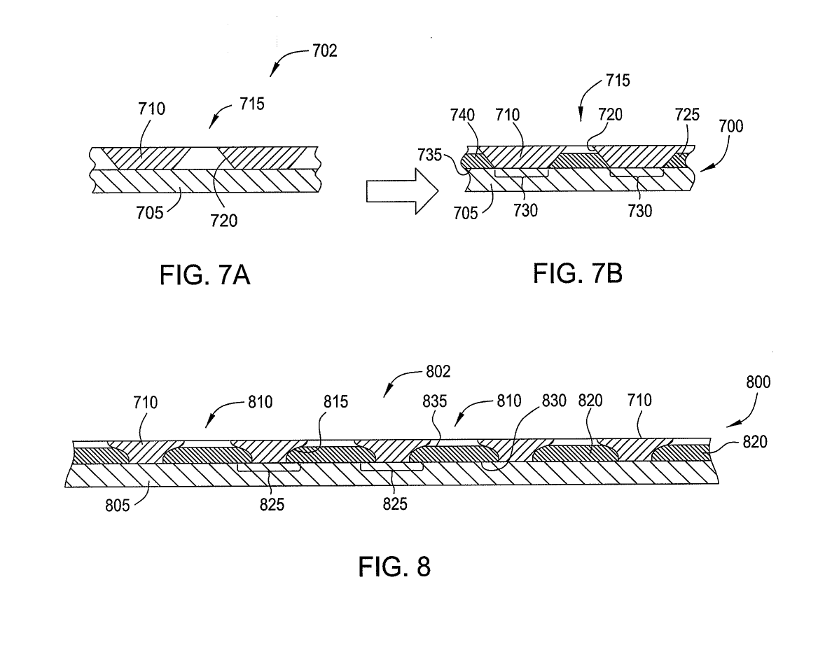

FIGS. 7A-7B are schematic partial sectional views illustrating a formation method for another embodiment of a fine metal mask 700. A portion of the fine metal mask 700 is shown in FIG. 7B. The fine metal mask 700 may be formed using a mask pattern 702 shown in FIG. 7A. The mask pattern 702 includes a mandrel 705 that may be the mandrel 305 described in FIGS. 3A-4B or the multi-layer mandrel 505 as described in FIGS. 5A and 5B. A dielectric material 710 is disposed on the mandrel 705 as described herein in other Figures. The dielectric material 710 may be the photoresist 310 described in FIGS. 3A-3C in one embodiment. In other embodiments, the dielectric material 710 may be the dielectric material 405 described and shown in FIGS. 4A through 5B. The dielectric material 710 may be the same thickness as the photoresist 310 described in FIGS. 3A-3C or the dielectric material 405 as described in FIGS. 4A and 4B. The dielectric material 405 may be patterned and/or formed by the same methods as described in FIGS. 3A-4B.

A plurality of openings 715 are formed in the dielectric material 710 after a photolithography process as described herein. In this embodiment, the openings 715 include a tapered sidewall 720. Thereafter, the mask pattern 702 is placed in an electrolytic bath (not shown). The bath includes a material with a low CTE metal dissolved therein, similar to the materials utilized in the embodiment described in FIG. 3C. An electrical bias is provided between the mandrel 705 and the low CTE metal in the bath. The openings 715 are then filled with the low CTE metal to form borders 725 of the fine metal mask 700. The borders 725 surround and isolate the dielectric material 710 remaining on the mandrel 705. Volumes 730 between the borders 725 will provide the fine openings 215 as described in FIG. 2 when the fine metal mask 700 is removed from the mandrel 705. The borders 725 may be formed to a height similar to the borders 335 described in FIG. 3C. The fine metal mask 700 may include a first side 735 and an opposing second side 740 such that the borders 725 may define a positive taper or a negative taper. The first side 735 may be placed against a substrate during formation of the sub-pixel active area 135 of the OLED device 100 of FIG. 1.

While the fine metal mask 600 shown in FIG. 6 and the fine metal mask 700 shown in FIG. 7 include borders 625 and 725, respectively, with linear sidewalls the that mirror the angles of the respective tapered sidewalls of the dielectric material, borders may be formed to have curved sidewalls. In some embodiments, the taper angle of the borders 625 and 725 also effects uniformity of deposition by shadowing the organic material at certain angles. To account for the shadow effect, the volumes 630 and 730 formed between the borders 625 and 725, respectively, may be significantly larger than sub-pixel active area 135 of the OLED device 100 of FIG. 1. In one embodiment, the volumes 630 and 730, which become the fine openings, define an open area that is about 4 times greater than a surface area of the sub-pixel active area. In some embodiments, the borders 625 and 725 are typically 12 um larger on each side than the sub-pixel active area 135. As one example, a 470 ppi sub-pixel active area 135 may include a length×width of about 6 um×about 36 um, and the fine openings would be about 18 um×about 48 um. However, opening sizes are limited since organic material of one sub-pixel should not be deposited over another sub-pixel (e.g., no blue or green on red, no red on green or blue, etc.).

FIG. 8 is a schematic partial sectional view illustrating a formation method for another embodiment of a fine metal mask 800. The fine metal mask 800 may be formed using a mask pattern 802. The mask pattern 802 includes a mandrel 805 that may be any of the mandrels as described herein. A dielectric material 710 is disposed on the mandrel 805 as described in FIGS. 7A. Openings 810 are formed in the dielectric material 710 after a photolithography process as described herein. In this embodiment, the openings 810 include a curved sidewall 815. Thereafter, the mask pattern 802 is placed in an electrolytic bath (not shown). The bath includes a material with a low CTE metal dissolved therein, similar to the materials utilized in the embodiment described in FIG. 3C. An electrical bias is provided between the mandrel 805 and the low CTE metal in the bath. The openings 810 are then filled with the low CTE metal to form borders 820 of the fine metal mask 800. The borders 820 surround and isolate the dielectric material 710 remaining on the mandrel 805. Volumes 825 between the borders 820 will provide the fine openings 215 as described in FIG. 2 when the fine metal mask 800 is removed from the mandrel 805. The borders 820 may be formed to a height similar to the borders 335 described in FIG. 3C. The fine metal mask 800 may include a first side 830 and an opposing second side 835 such that the borders 820 may define a positive curve or a negative curve. The first side 830 may be placed against a substrate during formation of the sub-pixel active area 135 of the OLED device 100 of FIG. 1. Alternatively, the second side 835 may be placed against a substrate during formation of the sub-pixel active area 135 of the OLED device 100 of FIG. 1.

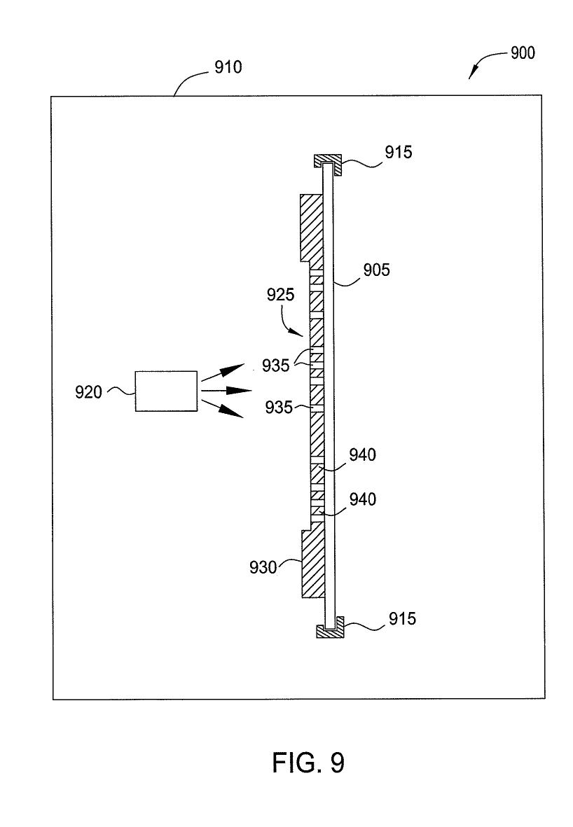

FIG. 9 schematically illustrates one embodiment of an apparatus 900 for forming an OLED device on a substrate 905. The apparatus 900 includes a deposition chamber 910 where the substrate 905 is supported in a substantially vertical orientation. The substrate 905 may be supported by a carrier 915 adjacent to a deposition source 920. A fine metal mask 925 is brought into contact with the substrate 905, and is positioned between the deposition source 920 and the substrate 905. The fine metal mask 925 may be any one of the fine metal masks 200, 300, 400, 500, 600, 700 or 800 as described herein. The fine metal mask 925 may be tensioned and coupled to a frame 930 by fasteners (not shown), welding or other suitable joining method. The deposition source 920 may be an organic material that is evaporated onto precise areas of the substrate 905, in one embodiment. The organic material is deposited through fine openings 935 formed in the fine metal mask 925 between borders 940 according to formation methods as described herein. The fine metal masks 200, 300, 400, 500, 600, 700 or 800 as described herein may comprise a single sheet having a pattern or multiple patterns of fine openings 935. Alternatively, the fine metal masks 200, 300, 400, 500, 600, 700 or 800 as described herein may be a series of sheets having a pattern or multiple patterns of fine openings 935 formed therein that are tensioned and coupled to the frame 930 in order to accommodate substrates of varying sizes.

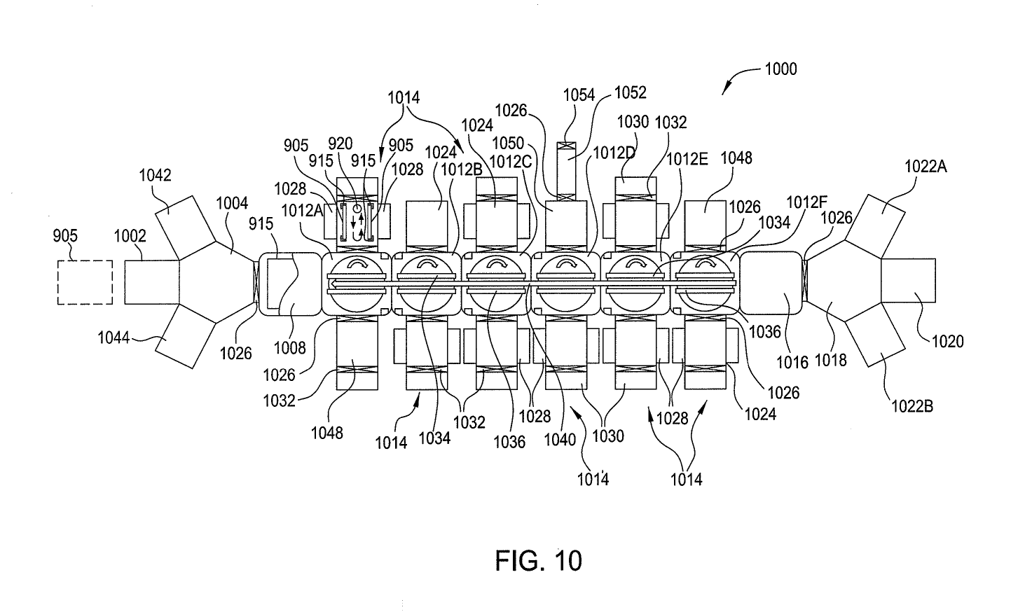

FIG. 10 is a schematic plan view of a manufacturing system 1000 according to one embodiment. The system 1000 may be used for manufacturing electronic devices, particularly electronic devices including organic materials therein. For example, the devices can be electronic devices or semiconductor devices, such as optoelectronic devices and, in particular, displays.

Embodiments described herein particularly relate to deposition of materials, for example. for display manufacturing on large area substrates. The substrates in the manufacturing system 1000 may be moved throughout the manufacturing system 1000 on carriers that may support one or more substrates at edges thereof, by electrostatic attraction, or combinations thereof. According to some embodiments, large area substrates or carriers supporting one or more substrates, for example large area carriers, may have a size of at least 0.174 m². Typically, the size of the carrier can be about 0.6 square meters to about 8 square meters, more typically about 2 square meters to about 9 square meters or even up to 12 square meters. Typically, the rectangular area, in which the substrates are supported and for which the holding arrangements, apparatuses, and methods according to embodiments described herein are provided, are carriers having sizes for large area substrates as described herein. For instance, a large area carrier, which would correspond to an area of a single large area substrate, can be GEN 5, which corresponds to about a 1.4 square meter substrate (1.1 m×1.3 m), GEN 7.5, which corresponds to about a 4.29 square meter substrate (1.95 m×2.2 m), GEN 8.5, which corresponds to about a 5.7 square meter substrate (2.2 m×2.5 m), or even GEN 10, which corresponds to about an 8.7 square meter substrate (2.85 m×3.05 m). Even larger generations, such as GEN 11 and GEN 12 and corresponding substrate areas can similarly be implemented. The fine metal masks 200, 300, 400, 500, 600, 700 or 800 as described herein may be sized accordingly.

According to typical embodiments, substrates may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

The manufacturing system 1000 shown in FIG. 10 includes a load lock chamber 1002, which is connected to a horizontal substrate handling chamber 1004. A substrate 905 (outlined in dashed lines), such as a large area substrate as described above, can be transferred from the substrate handling chamber 1004 to a vacuum swing module 1008. The vacuum swing module 1008 loads a substrate 905 in a horizontal position on a carrier 915. After loading the substrate 905 on the carrier 915 in the horizontal position, the vacuum swing module 1008 rotates the carrier 915 having the substrate 905 provided thereon in a vertical or substantially vertical orientation. The carrier 915 having the substrate 905 provided thereon is then transferred through a first transfer chamber 1012A and at least one subsequent transfer chamber (1012B-1012F) in the vertical orientation. One or more deposition apparatuses 1014 can be connected to the transfer chambers. Further, other substrate processing chambers or other vacuum chambers can be connected to one or more of the transfer chambers. After processing of the substrate 905, the carrier having a substrate 905 thereon is transferred from the transfer chamber 1012F into an exit vacuum swing module 1016 in the vertical orientation. The exit vacuum swing module 1016 rotates the carrier having a substrate 905 thereon from the vertical orientation to a horizontal orientation. Thereafter, the substrate 905 can be unloaded into an exit horizontal glass handling chamber 1018. The processed substrate 905 may be unloaded from the manufacturing system 1000 through load lock chamber 1020, for example, after the manufactured device is encapsulated in one of a thin-film encapsulation chamber 1022A or 1022B.

In FIG. 10, a first transfer chamber 1012A, a second transfer chamber 1012B, a third transfer chamber 1012C, a fourth transfer chamber 1012D, a fifth transfer chamber 1012E, and a sixth transfer chamber 1012F are provided. According to embodiments described herein, at least two transfer chambers are included in the manufacturing system 1000. In some embodiments, 2 to 8 transfer chambers can be included in the manufacturing system 1000. Several deposition apparatuses, for example 9 deposition apparatuses 1014 in FIG. 10, each having a deposition chamber 1024 and each being exemplarily connected to one of the transfer chambers are provided. According to some embodiments, one or more of the deposition chambers of the deposition apparatuses are connected to the transfer chambers via gate valves 1026.

At least a portion of the deposition chambers 1024 include one or more of the fine metal masks 200, 300, 400, 500, 600, 700 or 800 as described herein (not shown). Each of the deposition chambers 1024 also include a deposition source 920 (only one is shown) to deposit film layers on at least one substrate 905. In some embodiments, the deposition source 920 comprises an evaporation module and a crucible. In further embodiments, the deposition source 920 may be movable in the direction indicated by arrows in order to deposit a film on two substrates 905 supported on a respective carrier (not shown). Deposition is performed on the substrates 905 as the substrates 905 are in a vertical orientation or a substantially vertical orientation with a respective patterned mask between the deposition source 920 and each substrate 905. Each of the patterned masks include at least a first opening as described above. The first opening may be utilized to deposit a portion of a film layer outside of a pattern area of the patterned mask as described in detail above.

Alignment units 1028 can be provided at the deposition chambers 1024 for aligning substrates relative to the respective patterned mask. According to yet further embodiments, vacuum maintenance chambers 1030 can be connected to the deposition chambers 1024, for example via gate valve 1032. The vacuum maintenance chambers 1030 allow for maintenance of deposition sources in the manufacturing system 1000.

As shown in FIG. 10, the one or more transfer chambers 1012A-1012F are provided along a line for providing an in-line transportation system. According to some embodiments, a dual track transportation system is provided. The dual track transportation system includes a first track 1034 and a second track 1036 in each of the transfer chambers 1012A-1012F. The dual track transportation system may be utilized to transfer carriers 915 supporting substrates, along at least one of the first track 1034 and the second track 1036.

According to yet further embodiments, one or more of the transfer chambers 1012A-1012F are provided as a vacuum rotation module. The first track 1034 and the second track 1036 can be rotated at least 90 degrees, for example 90 degrees, 180 degrees or 360 degrees. The carriers, such as the carrier 915, moves linearly on the tracks 1034 and 1036. The carriers may be rotated in a position to be transferred into one of the deposition chambers 1024 of the deposition apparatuses 1014, or one of the other vacuum chambers described below. The transfer chambers 1012A-1012F are configured to rotate the vertically oriented carriers and/or substrates, wherein, for example, the tracks in the transfer chambers are rotated around a vertical rotation axis. This is indicated by the arrows in the transfer chambers 1012A-1012F of FIG. 10.

According to some embodiments, the transfer chambers are vacuum rotation modules for rotation of a substrate under a pressure below 10 mbar. According to yet further embodiments, another track is provided within the two or more transfer chambers (1012A-1012F), wherein a carrier return track 1040 is provided. According to typical embodiments, the carrier return track 1040 can be provided between the first track 1034 and second track 1036. The carrier return track 1040 allows for returning empty carriers from the further the exit vacuum swing module 1016 to the vacuum swing module 1008 under vacuum conditions. Returning the carriers under vacuum conditions and, optionally under controlled inert atmosphere (e.g. Ar, N₂ or combinations thereof) reduces the carriers' exposure to ambient air. Contact with moisture can therefore be reduced or avoided. Thus, the outgassing of the carriers during manufacturing of the devices in the manufacturing system 1000 can be reduced. This may improve the quality of the manufactured devices and/or the carriers can be in operation without being cleaned for an extended time period.

FIG. 10 further shows a first pretreatment chamber 1042 and a second pretreatment chamber 1044. A robot (not shown) or another suitable substrate handling system can be provided in the substrate handling chamber 1004. The robot or other substrate handling system can load the substrate 905 from the load lock chamber 1002 in the substrate handling chamber 1004 and transfer the substrate 905 into one or more of the pretreatment chambers (1042, 1044). For example, the pretreatment chambers can include a pretreatment tool selected from the group consisting of: plasma pretreatment of the substrate, cleaning of the substrate, UV and/or ozone treatment of the substrate, ion source treatment of the substrate, RF or microwave plasma treatment of the substrate, and combinations thereof. After pretreatment of the substrates, the robot or other handling system transfers the substrate out of pretreatment chamber via the substrate handling chamber 1004 into the vacuum swing module 1008. In order to allow for venting the load lock chamber 1002 for loading of the substrates and/or for handling of the substrate in the substrate handling chamber 1004 under atmospheric conditions, a gate valve 1026 is provided between the substrate handling chamber 1004 and the vacuum swing module 1008. Accordingly, the substrate handling chamber 1004, and if desired, one or more of the load lock chamber 1002, the first pretreatment chamber 1042 and the second pretreatment chamber 1044, can be evacuated before the gate valve 1026 is opened and the substrate is transferred into the vacuum swing module 1008. Accordingly, loading, treatment and processing of substrates may be conducted under atmospheric conditions before the substrate is loaded into the vacuum swing module 1008.

According to embodiments described herein, loading, treatment and processing of substrates, which may be conducted before the substrate is loaded into the vacuum swing module 1008, is conducted while the substrate is horizontally oriented or essentially horizontally oriented. The manufacturing system 1000 as shown in FIG. 10, and according to yet further embodiments described herein, combines a substrate handling in a horizontal orientation, a rotation of the substrate in a vertical orientation, material deposition onto the substrate in the vertical orientation, a rotation of the substrate in a horizontal orientation after the material deposition, and an unloading of the substrate in a horizontal orientation.

The manufacturing system 1000 shown in FIG. 10, as well as other manufacturing systems described herein, include at least one thin-film encapsulation chamber. FIG. 10 shows a first thin-film encapsulation chamber 1022A and a second thin-film encapsulation chamber 1022B. The one or more thin-film encapsulation chambers include an encapsulation apparatus, wherein the deposited and/or processed layers, particularly an OLED material, are encapsulated between, i.e. sandwiched between, the processed substrate and another substrate in order to protect the deposited and/or processed material from being exposed to ambient air and/or atmospheric conditions. Typically, the thin-film encapsulation can be provided by sandwiching the material between two substrates, for example glass substrates. However, other encapsulation methods like lamination with glass, polymer or metal sheets, or laser fusing of a cover glass may alternatively be applied by an encapsulation apparatus provided in one of the thin-film encapsulation chambers. In particular, OLED material layers may suffer from exposure to ambient air and/or oxygen and moisture. Accordingly, the manufacturing system 1000, for example as shown in FIG. 10, can encapsulate the thin films before unloading the processed substrate via the exit load lock chamber 1020.

According to yet further embodiments, the manufacturing system can include a carrier buffer 1048. For example, the carrier buffer 1048 can be connected to the first transfer chamber 1012A, which is connected to the vacuum swing module 1008 and/or the last transfer chamber, i.e. the-sixth transfer chamber 1012F. For example, the carrier buffer 1048 can be connected to one of the transfer chambers, which is connected to one of the vacuum swing modules. Since the substrates are loaded and unloaded in the vacuum swing modules, it is beneficial if the carrier buffer 1048 is provided close to a vacuum swing module. The carrier buffer 1048 is configured to provide the storage for one or more, for example 5 to 30, carriers. The carriers in the buffer can be used during operation of the manufacturing system 1000 in the event another carrier needs to be replaced, for example for maintenance, such as cleaning.

According to yet further embodiments, the manufacturing system can further include a mask shelf 1050, i.e. a mask buffer. The mask shelf 1050 is configured to provide storage for replacement patterned masks and/or masks, which need to be stored for specific deposition steps. According to methods of operating a manufacturing system 1000, a mask can be transferred from the mask shelf 1050 to a deposition apparatus 1014 via the dual track transportation arrangement having the first track 1034 and the second track 1036. Thus, a mask in a deposition apparatus can be exchanged either for maintenance, such as cleaning, or for a variation of a deposition pattern without venting a deposition chamber 1024, without venting a transfer chambers 1012A-1012F, and/or without exposing the mask to atmospheric conditions.

FIG. 10 further shows a mask cleaning chamber 1052. The mask cleaning chamber 1052 is connected to the mask shelf 1050 via gate valve 1026. Accordingly, a vacuum tight sealing can be provided between the mask shelf 1050 and the mask cleaning chamber 1052 for cleaning of a mask. According to different embodiments, a fine metal masks 200, 300, 400, 500, 600, 700 or 800 as described herein can be cleaned within the manufacturing system 1000 by a cleaning tool, such as a plasma cleaning tool. A plasma cleaning tool can be provided in the mask cleaning chamber 1052. Additionally or alternatively, another gate valve 1054 can be provided at the mask cleaning chamber 1052, as shown in FIG. 10. Accordingly, a mask can be unloaded from the manufacturing system 1000 while only the mask cleaning chamber 1052 needs to be vented. By unloading the mask from the manufacturing system, an external mask cleaning can be provided while the manufacturing system continues to be fully operating. FIG. 10 illustrates the mask cleaning chamber 1052 adjacent to the mask shelf 1050. A corresponding or similar cleaning chamber (not shown) may also be provided adjacent to the carrier buffer 1048. By providing a cleaning chamber adjacent to the carrier buffer 1048, the carrier may be cleaned within the manufacturing system 1000 or can be unloaded from the manufacturing system through the gate valve connected to the cleaning chamber.

Embodiments of the fine metal masks 200, 300, 400, 500, 600, 700 or 800 as described herein may be utilized in the manufacture of high resolution displays. The fine metal masks 200, 300, 400, 500, 600, 700 or 800 as described herein may include sizes of about 750 mm×650 mm according to one embodiment. A fine metal mask of this size may be a full sheet (750 mm×650 mm) that is tensioned in two-dimensions. Alternatively, a fine metal mask of this size may be a series of strips that are tensioned in one-dimension to cover a 750 mm×650 mm area. Larger fine metal mask sizes include about 920 mm×about 730 mm, GEN 6 half-cut (about 1500 mm×about 900 mm), GEN 6 (about 1500 mm×about 1800 mm), GEN 8.5 (about 2200 mm×about 2500 mm) and GEN 10 (about 2800 mm×about 3200 mm). In at least the smaller sizes, a pitch tolerance between fine openings of the fine metal masks 200, 300, 400, 500, 600, 700 or 800 as described herein may be about +/−3 μm per a 160 mm length.

Utilizing electroforming techniques in the manufacture of the fine metal masks 200, 300, 400, 500, 600, 700 or 800 as described herein has a substantial advantage over conventional forming processes. Standard opening sizes in conventional masks may have a variation of about +/−2 um to 5 um which is due to variations of the chemical etching process when forming fine openings in the mask. In contrast, the mask patterns 302, 402, 502, 602, 702 or 802 as described herein are formed by photolithography techniques. Thus, variations in sizes of the fine openings are less than about 0.2 um. That provides an advantage as resolution increases Thus, the fine metal masks 200, 300, 400, 500, 600, 700 or 800 as described herein may have more uniform opening size (due to the better control by photolithography techniques). The fine metal masks 200, 300, 400, 500, 600, 700 or 800 as described herein may also have a very consistent mask-to-mask uniformity. The uniformity may be improved not only in opening size, but pitch accuracy, as well as other properties may be improved.

The fine metal masks 200, 300, 400, 500, 600, 700 or 800 as described herein may be used to form the sub-pixel active areas 135 of the OLED device 100 shown in FIG. 1 with high accuracy. For example, the uniformity of each of the RGB layers of the organic material layers 120 of the OLED device 100 is high, such as greater than about 95%, for example, greater than 98%. The fine metal masks 200, 300, 400, 500, 600, 700 or 800 as described herein meet these accuracy tolerances.

While the foregoing is directed to embodiments of the present disclosure, other and further embodiments of the disclosure may be devised without departing from the basic scope thereof. Therefore, the scope of the present disclosure is determined by the claims that follow.

1. A shadow mask, comprising:
a frame made of a metallic material; and
one or more mask patterns coupled to the frame, the one or more mask patterns comprising a metal having a coefficient of thermal expansion less than or equal to about 14 microns/meter/degrees Celsius and having a plurality of openings formed therein, the metal having a thickness of about 5 microns to about 50 microns and having a pitch tolerance between openings of about +/−3 microns across a length of about 160 millimeters.

2. The shadow mask of claim 1, wherein each of the plurality of openings includes a major dimension of about 5 microns to about 20 microns.

3. The shadow mask of claim 1, wherein each of the plurality of openings includes tapered sidewalls.

4. The shadow mask of claim 3, wherein each of the plurality of openings includes an open area that is about 4 times greater than a sub-pixel active area formed by the respective opening.

5. The shadow mask of claim 1, wherein each of the plurality of openings includes curved sidewalls.

6. The shadow mask of claim 5, wherein each of the plurality of openings includes an open area that is about 4 times greater than a sub-pixel active area formed by the respective opening.

7. The shadow mask of claim 1, wherein the metal comprises an alloy of iron (Fe), nickel (Ni) and cobalt (Co).

8. (canceled)

9. A mask pattern, comprising:
a mandrel comprising a conductive material and having a coefficient of thermal expansion less than or equal to about 7 microns/meter/degrees Celsius; and
a dielectric material having a plurality of openings formed therein exposing at least a portion of the conductive material, the dielectric material comprising a pattern of volumes, each of the volumes having a major dimension of about 5 microns to about 20

10. The mask pattern of claim 9, wherein the dielectric material comprises a photoresist material.

11. The mask pattern of claim 9, wherein the dielectric material comprises an inorganic insulating material.

12. The mask pattern of claim 9, wherein the mandrel comprises a first substrate and a second substrate.

13. The mask pattern of claim 12, wherein the first substrate comprises a glass material or a glass ceramic material.

14. The mask pattern of claim 12, wherein the second substrate comprises the conductive material, and the second substrate includes a coefficient of thermal expansion greater than a coefficient of thermal expansion of the first substrate.

15. The mask pattern of claim 12, wherein second substrate comprises a plurality of metallic layers and wherein a thickness of the metallic layers is dependent upon a surface area of the first substrate.

16. (canceled)

17. (canceled)

18. (canceled)

19. (canceled)

20. (canceled)

21. (canceled)

22. An electroformed mask, formed by:
preparing a mandrel comprising a metal layer and a pattern area having openings formed therein exposing a portion of the metal layer, the mandrel having a coefficient of thermal expansion less than or equal to about 7 microns/meter/degrees Celsius;
exposing the mandrel to an electrolytic bath;
electrodepositing a metallic material having a coefficient of thermal expansion less than or equal to about 14 microns/meter/degrees Celsius in the openings;
removing the mandrel from the bath; and
separating the mask from the mandrel.

23. The electroformed mask of claim 22, wherein the mask has a plurality of borders comprising the metallic material, and a pitch tolerance between the borders is about +/−3 microns across a length of about 160 millimeters.

24. The electroformed mask of claim 22, wherein pattern area comprises a dielectric material that is patterned by photolithography.

25. The electroformed mask of claim 24, wherein the dielectric material comprises a photoresist material.

26. The electroformed mask of claim 24, wherein the dielectric material comprises an inorganic insulating material.

27. The electroformed mask of claim 22, wherein the mandrel comprises a first substrate and a second substrate, and the first substrate comprises a glass material or a glass ceramic material.

28. (canceled)

29. (canceled)
